(19) United States
(12) Patent Application Publication
(10) Pub. No.: US 2025/0234491 A1
(43) Pub. Date: Jul. 17, 2025

(54) Electrically Isolating Heat Pipe Assembly

(71) Applicant: TE Connectivity Solutions GmbH, Schaffhausen (CH)

(72) Inventor: Matthew MISHRIKEY, Roslindale, MA (US)

(73) Assignee: TE Connectivity Solutions GmbH, Schaffhausen (CH)

(21) Appl. No.: 18/983,496

(22) Filed: Dec. 17, 2024

Related U.S. Application Data
(60) Provisional application No. 63/619,771, filed on Jan. 11, 2024.

(51) Int. Cl. H05K 7/20

(52) U.S. Cl. CPC H05K 7/20336; H05K 7/20309; H05K 7/20318

(57) ABSTRACT

A heat pipe assembly for use in cooling a first member in a high voltage environment and a method of assembling the heat pipe assembly. The heat pipe assembly includes a first section thermally attached to the first member and a third section thermally attached to a second member. A second section is positioned between the first section and the third section, the second section being made of non-conductive flexible material which does not fail at high temperatures.

### CROSS REFERENCE TO RELATED APPLICATIONS

This application claims priority to U.S. Provisional Patent Application Ser. No. 63/619,771 filed on Jan. 11, 2024 which is incorporated herein by reference in its entirety.

### FIELD OF THE INVENTION

The invention relates to a heat pipe assembly which provides electrical isolation. In particular, the invention is directed to a heat pipe assembly which has an electrically isolating portion between the evaporator and the condenser of the heat pipe assembly.

### BACKGROUND OF THE INVENTION

It is often necessary to extract and remove heat from assemblies to maintain good working function of the assembly, and to prevent overheating or poor performance. There are many methods to do this. One very high performance approach is to utilize heat pipes. A heat pipe generally utilizes two phases, gas and liquid, of a working fluid, to transfer heat from an evaporator to a condenser. Heat transfer occurs in the evaporator when condensate is vaporized, and in the condenser when gaseous vapor condenses.

In various applications, a wick assists the transfer of condensate from the condenser back to the evaporator and allows some function against gravity. Other applications use a thermosiphon which utilizes gravity to transfer condensate back to the evaporator, without any wick. In such applications, the condenser must be above the evaporator. In other applications, a loop heat pipe or loop thermosiphon allow the flows of vapor and of condensate to happen in their own dedicated loop sections. This prevents a limitation in single tube heat pipes where vapor velocity shears condensate from the wick, interrupting the vapor cycle.

The region between the evaporator and the condenser is known as the adiabatic section of the heat pipe.

In some electrical assemblies, voltages may be significant. Care must be taken to separate high voltage conductors to avoid arcing, partial discharge, corona discharge, and the like. Often when a part needs to be cooled, this can be done with the application of a heat sink. The sink may be convectively cooled (fins), electroactively cooled (Peltier junctions), or liquid cooled (cold plate). In the case of a liquid cooled cold plate, these are generally constructed of a metal block. In order to cool a part such as a bus bar, wire, or connector that is at a high electrical potential, care must be taken to isolate the cold plate and the part at high potential, to prevent any short circuit, or possibility of arc fault. This isolation may be achieved with a thermal insulating material (TIM). The TIM is thermally conductive but electrically isolating.

It is difficult to find a very efficient high performance TIM because electrical and thermal conductivity of any bulk material are correlated. Commercial TIMs that are considered high performance may be lucky to approach 1 W/mK. For reference, bulk copper is 400 W/mK, and heat pipes can approach 100,000 W/mK.

Conventional copper tube heat pipes are electrically conductive, and can therefore not be used as-is to cool parts in need of electrical isolation. Using a TIM to provide isolation at the heat pipe to cold plate interface, or at the hot object to heat pipe interface would allow for isolation, but would severely degrade thermal performance.

It would therefore be beneficial to provide thermal heat pipe assembly with desired thermal properties, while also providing needed electrical isolation. In particular, it would be beneficial to provide a heat pipe assembly which has an electrically isolating portion between the evaporator and the condenser of the heat pipe to allow the heat pipe assembly to be used in electrical assemblies which have voltage requirements.

### SUMMARY OF THE INVENTION

The following provides a summary of certain illustrative embodiments of the present invention. This summary is not an extensive overview and is not intended to identify key or critical aspects or elements of the present invention or to delineate its scope.

An object is to provide a thermal heat pipe assembly with desired thermal properties, while also providing needed electrical isolation.

An object is to provide a heat pipe assembly with an electrically isolating portion between the evaporator and the condenser of the heat pipe to allow the heat pipe assembly to be used in electrical assemblies which have voltage requirements.

An object is to provide a heat pipe assembly with an electrically isolating portion and which utilizes a working fluid which is non-conductive and non-corrosive. An optional wick may be provided, the wick being a non-conductive material or mixed material.

An embodiment is directed to a heat pipe assembly for use in cooling a first member in a high voltage environment. The heat pipe assembly includes a first section thermally attached to the first member and a third section thermally attached to a second member. A second section is positioned between the first section and the third section, the second section being made of non-conductive flexible material which does not fail at high temperatures.

The second section is made of material which allows the second section to be bent without kinking under mechanical stress. The second section is attached to the first section and the third section in a manner which allow a vacuum to be maintained in the entire heat pipe assembly. The second section is positioned over respective ends of the first section and the third section, an inner diameter of the second section is dimensioned to be slightly smaller than an outer diameter of the first section and an outer dimension of the third section, the second section is stretched to fit over the first section and the third section, thereby assisting the sealing function between the second section and the first section and the second section and the third section.

An embodiment is directed to a method of making a heat pipe assembly for use in cooling a first member in a high voltage environment, the method comprising: mating and securing a capped first section of the heat pipe assembly to a second section of the heat pipe assembly; mating and securing a third section of the heat pipe assembly, with two open ends, to an open end of the second section; inserting a working fluid into the heat pipe assembly through the open end of the third section; heating the heat pipe assembly to initiate vaporization of the working fluid; capping and sealing the open end of the third section; and establishing a vacuum in the heat pipe assembly near the vapor point of working fluid.

Additional features and aspects of the present invention will become apparent to those of ordinary skill in the art upon reading and understanding the following detailed description of the exemplary embodiments. As will be appreciated by the skilled artisan, further embodiments of the invention are possible without departing from the scope and spirit of the invention. Accordingly, the drawings and associated descriptions are to be regarded as illustrative and not restrictive in nature.

### BRIEF DESCRIPTION OF THE DRAWINGS

FIG. 1 is perspective view of a first illustrative heat pipe assembly of the present invention, the heat pipe assembly conducting heat from a first component to a second component.

FIG. 2 is a cross-sectional view of the heat pipe assembly taken along line 2-2 of FIG. 1.

FIG. 3 is perspective view of a second illustrative heat pipe assembly of the present invention, the heat pipe assembly conducting heat from a first component to a second component.

FIG. 4 is a cross-sectional view of the heat pipe assembly taken along line 4-4 of FIG. 3.

FIG. 5 is perspective view of a third illustrative heat pipe assembly of the present invention, the heat pipe assembly conducting heat from a first component to a second component, with second sections having clamps provided at the ends thereof.

FIG. 6 is perspective view of a fourth illustrative heat pipe assembly of the present invention, the heat pipe assembly conducting heat from a first component to a second component, with second sections having heat shrink provided at the ends thereof.

The accompanying drawings, which are incorporated into and form a part of the specification, schematically illustrate one or more exemplary embodiments of the invention and, together with the general description given above and detailed description given below, serve to explain the principles of the invention.

### DETAILED DESCRIPTION OF THE INVENTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. In various applications, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combination of features that may exist alone or in other combinations of features, the scope of the invention being defined by the claims appended hereto.

Exemplary embodiments of the present invention are now described with reference to the Figures. Reference numerals are used throughout the detailed description to refer to the various elements and structures. Although the following detailed description contains many specifics for the purposes of illustration, a person of ordinary skill in the art will appreciate that many variations and alterations to the following details are within the scope of the invention. Accordingly, the following embodiments of the invention are set forth without any loss of generality to, and without imposing limitations upon, the claimed invention.

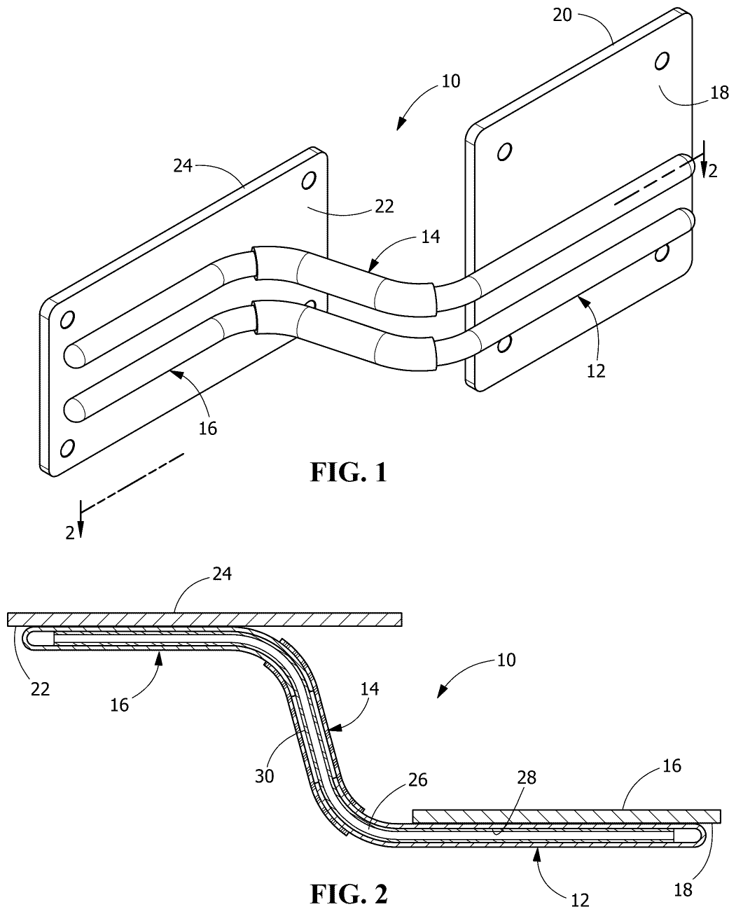

As shown in FIG. 1, a pair of heat pipe assemblies 10 are shown. While two heat pipe assemblies 10 are shown proximate to and parallel to each other, other numbers and configurations of heat pipe assemblies may be used.

Each illustrative heat pipe assembly 10 shown in FIGS. 1 and 2 have a first section 12, a second or transition section 14, and a third section 16. In the illustrative embodiment shown, each heat pipe assembly 10 has a generally stretched S-configuration. However, other shapes and configurations of the heat pipe assembly 10 may be used.

In the embodiment shown, the first section 12 is mounted in thermal engagement with a surface 18 of a first member 20. The first section 12 may be mounted to the surface 18 by known methods, such as, but not limited to, soldered, glued, press-fit, bolted or made of a single stock with the surface 18. The first section 12 is made from material, such as, but not limited to, copper, which has the required thermal transfer properties required. In this embodiment the first member 20 generates heat which must be removed from the first member 20 to allow for proper operation of the first member 20. The first section 12 of the heat pipe assembly 10 is positioned to draw heat from the surface 18 of a first member 20. Therefore, in the illustrative embodiment shown, the first section 12 of the heat pipe assembly 10 is configured to act as the condenser in the heat pipe assembly 10.

In the embodiment shown, the third section 16 is mounted in thermal engagement with a surface 22 of a second member 24. The third section 16 may be mounted to the surface 22 by known methods, such as, but not limited to, soldered, glued, press-fit, bolted or made of a single stock with the surface 18. The third section 16 is made from material, such as, but not limited to, copper, which has the required thermal transfer properties required. In this embodiment the second member 24 is configured to expel the heat which must be removed from the first member 20. The third section 16 of the heat pipe assembly 10 is positioned to allow heat from the third section 16 to be transferred to the surface 12 of a second member 24. Therefore, in the illustrative embodiment shown, the third section 16 of the heat pipe assembly 10 is configured to act as the evaporator in the heat pipe assembly 10.

In the embodiment shown, the second section 14 is positioned between the first section 12 and the third section 16. The second section 14 is made of non-conductive flexible material which does not fail at high temperatures, such as, but not limited to, tubing used in automotive applications. The material may be a stiff, yet flexible, or reinforced material which allows the second section 14 to be bent without kinking under mechanical stress. The second section 14 is attached to the first section 12 and the third section 16 in a manner which allow a vacuum to be maintained in the entire heat pipe assembly 10. For example, the second section 14 may be glued, cemented or epoxied to the first section 12 and the third section 16.

In the embodiment shown in FIGS. 1 and 2, the second section 14 is positioned over the ends of the first section 12 and the third section 16. In the illustrative embodiment shown, the inner diameter of the second section 14 is dimensioned to be slightly smaller than the outer diameter of the first section 12 and the third section 16, such second section 14 is stretched to fit over the first section 12 and the third section 16, thereby assisting the sealing function between the second section 14 and the first section 12 and the third section 16. However, in other embodiments the inner diameter of the second section 14 may be dimensioned to be the same size or slightly larger the outer diameter of the first section 12 and the third section 16, so long as the second section 14 is properly sealed to the first section 12 and the third section 16 by means of adhesive or the like.

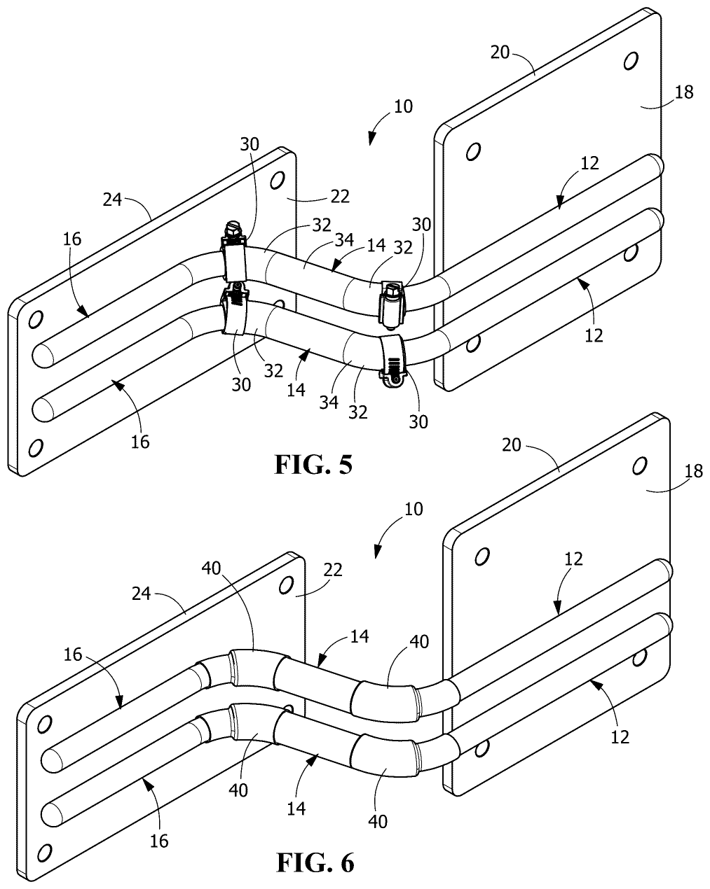

In order to ensure that the second section 14 is sealed to the first section 12 and the third section 16, clamps 30 may positioned over the ends 32 of the second section 14, as shown in FIG. 5. As the ends 32 extend over the first section 12 and the third section 16, as the clamps 30 are tightened, the clamps 30 cause the material of the walls 34 of the second section 14 to be compressed onto the first section 12 and the third section 16. This helps to ensure that the second section 14 is properly sealed to the first section 12 and the third section 16, thereby ensuring that the vacuum is maintained in the entire heat pipe assembly 10. The type of clamps used is not limited to that shown in FIG. 5. Various clamps, such as, but not limited to, constant tension spring clamps, band clamps, bolt clamps, and worm-drive clamps.

Alternatively, one or more heat shrink members 40 may positioned over the ends of the second sections 14 to ensure that the second sections 14 are sealed to the first sections 12 and the third sections 16, as shown in FIG. 6. In the illustrative embodiment shown, individual heat shrink members 40 are positioned at each end of the second sections 14. However, other embodiments of the heat shrink may be used, including, but not limited to, a single heat shrink member which extends over the length of each second section 14. In addition, the second sections 14 may be made of material which allows the second sections to be partially heat shrinkable at desired locations, such as the ends 32 of the second sections 14. Regardless of the configuration of the heat shrink member, the heat shrink member 40 is exposed to localize heat which causes the heat shrink member 40 to soften and flow around the ends of the first section 12 and the third section 16. This helps to ensure that the second section 14 is properly sealed to the first section 12 and the third section 16, thereby ensuring that the vacuum is maintained in the entire heat pipe assembly 10.

The heat pipe assembly 10 has a working fluid 26 which is provided in the inner cavity 28 of the heat pipe assembly 10. The inner cavity 28 extends from the first section 12, through the second section 14, and into the third section 16. The working fluid 26 is a non-conductive material. In addition, the working fluid 26 is non-corrosive to the material of the first section 12 and the third section 16, and non-corrosive to the material of the second section 14. The working fluid 26 must not attack or degrade the material which attaches the second section 14 to the first section 12 and the third section 16. Examples of the working fluid 26 include, but are not limited to, HFEs such as 3M Novec.

In various applications, a wick 30 may be provided in the inner cavity 28 of the heat pipe assembly 10. The wick 30 operates in a known manner to facilitate the flow of the working fluid 26 in various applications. The wick 30 is made of a non-conductive material, such as, but not limited to fiber, woven cloth, or fiberglass. Alternatively, the wick 30 may be made of a mixed material. For example, the first section 12 and the third section 16 may have grooved or sintered wicks (integrated in the walls of the first section 12 and the third section 16) and the second or adiabatic section 14 could have a woven fiber wick.

During assembly of the heat pipe assembly 10, the first section 12 with a capped end is mated and glued with the second section 14. The length of the second section 14 must be significant enough that the distance between the first section 12 and the third section 16 is greater than the creepage/clearance distances required for operation at a designated altitude. The third section 16, with two open ends, is mated and glued to the open end of second section 14. If a wick 30 is needed, the wick 30 is inserted through the open end of the third section 16. The working fluid 26 is added to assembly through the open end of the third section 16. The amount of working fluid 26 may vary, depending on fluid, pipe length, etc., but it is typical to add only a small amount approximating a few drops. The heat pipe assembly 10 is then heated to initiate vaporization of fluid. The open end of third section 16 is than capped and sealed. As the heat pipe assembly 10 cools a vacuum is established near the vapor point of working fluid.

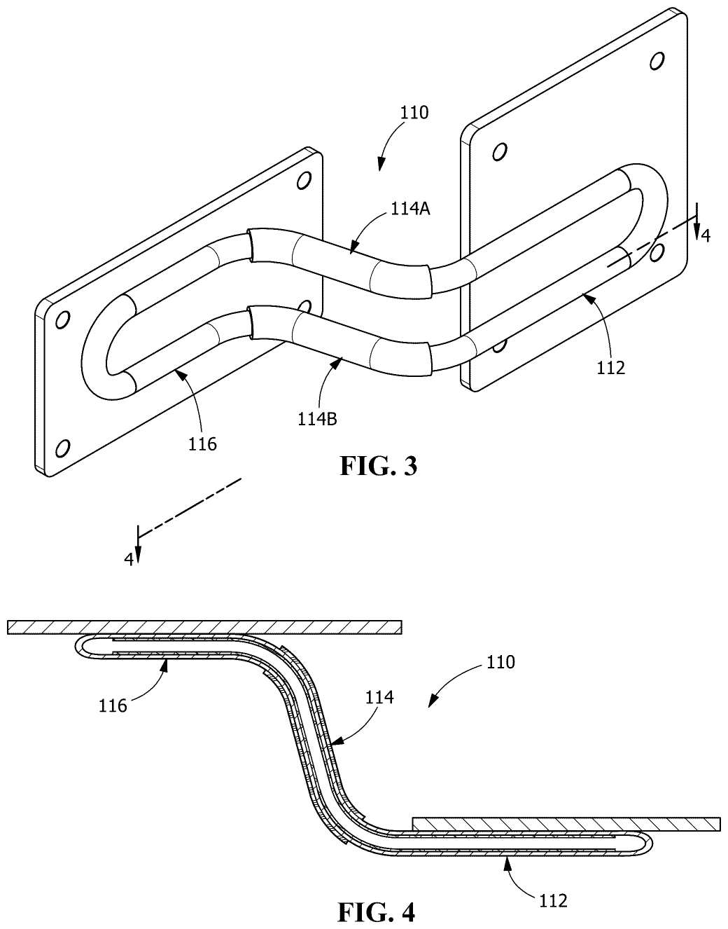

The illustrative embodiment of the heat pipe assembly 110 shown in FIGS. 3 and 4 is similar to the heat pipe assembly 10 shown in FIGS. 1 and 2. However, the heat pipe assembly 110 is a loop heat pipe or a loop thermosiphon. The loop allows condensate to flow continuously in one direction unencumbered by shear forces of vapor moving at shearing velocity.

In this embodiment, the first section 112 and the third section 116 are U-shaped members. The second section 114 is two sections 114A and 114B. The remaining description of the first section 12, second section 14 and third section 16 of the first illustrative embodiment apply to the first section 112, second section 114 and third section 116 of this second illustrative embodiment. In addition, clamps and heat shrink members may be used to seal the heat pipe assembly 110 in the same manner described above.

By incorporating the second section of the heat pipe assembly 10, 110, the heat pipe assembly of the present invention can be used in electrically isolating applications. The material of the second section 14, 114 allows for movement of the first member 20 relative to the second member 24 due to shock and vibration in the system.

The heat pipe assemblies 10, 110 can be used in applications in which the size and spacing of the components is small, such as, but not limited to electrical connector or electrically conductive elements. The use of one or more heat pipe assemblies 10,110 allows the cooling of high voltage parts with high efficiencies. Conventional solutions using TIM materials cannot compare in performance to heat pipe based assembly of the present invention.

While the invention has been described with reference to a preferred embodiment, it will be understood by those skilled in the art that various changes may be made and equivalents may be substituted for elements thereof without departing from the spirit and scope of the invention as defined in the accompanying claims. One skilled in the art will appreciate that the invention may be used with many modifications of structure, arrangement, proportions, sizes, materials and components and otherwise used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

What is claimed:

1. A heat pipe assembly for use in cooling a first member in a high voltage environment, the heat pipe assembly comprising:
a first section thermally attached to the first member;
a second section;
a third section thermally attached to a second member;
the second section positioned between the first section and the third section, the second section being made of non-conductive flexible material which does not fail at high temperatures.

2. The heat pipe assembly as recited in claim 1, wherein second section is made of material which allows the second section to be bent without kinking under mechanical stress.

3. The heat pipe assembly as recited in claim 1, wherein the second section is attached to the first section and the third section in a manner which allow a vacuum to be maintained in the entire heat pipe assembly.

4. The heat pipe assembly as recited in claim 1, wherein the second section is positioned over respective ends of the first section and the third section, an inner diameter of the second section is dimensioned to be slightly smaller than an outer diameter of the first section and an outer dimension of the third section, the second section is stretched to fit over the first section and the third section, thereby assisting the sealing function between the second section and the first section and the second section and the third section.

5. The heat pipe assembly as recited in claim 4, wherein clamps are provided at ends of the second section, whereby the clamps compress walls of the second section onto the first section and the third section to provide proper sealing between the second section and the first section and the third section, ensuring that the vacuum is maintained in the entire heat pipe assembly.

6. The heat pipe assembly as recited in claim 4, wherein one or more heat shrink members are positioned over ends of the second sections, whereby the one or more heat shrink members provide proper sealing between the second section and the first section and the third section, ensuring that the vacuum is maintained in the entire heat pipe assembly.

7. The heat pipe assembly as recited in claim 1, wherein the first section is made from material which has the required thermal transfer properties required.

8. The heat pipe assembly as recited in claim 7, wherein the third section is made from material which has the required thermal transfer properties required.

9. The heat pipe assembly as recited in claim 8, wherein the first section is a condenser in the heat pipe assembly.

10. The heat pipe assembly as recited in claim 9, wherein the third section is an evaporator in the heat pipe assembly.

11. The heat pipe assembly as recited in claim 10, wherein the first section is made from copper.

12. The heat pipe assembly as recited in claim 11, wherein the third section is made from copper.

13. The heat pipe assembly as recited in claim 1, wherein the heat pipe assembly has a working fluid which is provided in an inner cavity of the heat pipe assembly, the inner cavity extends from the first section, through the second section, and into the third section, the working fluid is a non-conductive material.

14. The heat pipe assembly as recited in claim 13, wherein a wick is be provided in the inner cavity of the heat pipe assembly, the wick is made of a non-conductive material.

15. The heat pipe assembly as recited in claim 1, wherein a distance between the first section and the third section is greater than the creepage/clearance distances required for operation at a designated altitude.

16. The heat pipe assembly as recited in claim 1, wherein the heat pipe assembly is a loop heat pipe assembly.

17. The heat pipe assembly as recited in claim 1, wherein the heat pipe assembly is a thermosiphon heat pipe assembly.

18. A method of making a heat pipe assembly for use in cooling a first member in a high voltage environment, the method comprising:
mating and securing a capped first section of the heat pipe assembly to a second section of the heat pipe assembly;
mating and securing a third section of the heat pipe assembly, with two open ends, to an open end of the second section;
inserting a working fluid into the heat pipe assembly through the open end of the third section;
heating the heat pipe assembly to initiate vaporization of the working fluid;
capping and sealing the open end of the third section;
establishing a vacuum in the heat pipe assembly near the vapor point of working fluid.

19. The method as recited in claim 18, further comprising inserting a wick through the open end of the third section prior to capping the open end of the third section.

20. The method as recited in claim 18, wherein the second section is made of non-conductive flexible material which does not fail at high temperatures.
